(19) United States
(12) Patent Application Publication
(10) Pub. No.: US 2007/0018696 A1
(43) Pub. Date: Jan. 25, 2007

(54) Transmitting circuit and semiconductor integrated circuit

(75) Inventor: Jeong-Don Lim, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/481,369

(22) Filed: Jul. 5, 2006

(30) Foreign Application Priority Data
Jul. 25, 2005 (KR) 2005-67409

(51) Int. Cl. H03B 1/00

(52) U.S. Cl. 327/112; 327/206

(57) ABSTRACT

A transmitting circuit includes an internal circuit, a first dividing circuit, a second dividing circuit, a delay circuit, a first switching circuit, and a second switching circuit. The first dividing circuit is coupled between a first power voltage and the internal circuit, and the second dividing circuit is coupled between a second power voltage and the internal circuit. The delay circuit is configured to generate a switching control signal by delaying an output signal of the internal circuit for a delay time. The first switching circuit is coupled in parallel to the first dividing circuit, wherein the first switching circuit is coupled between the first power voltage and the internal circuit and is configured to be switched in response to the switching control signal.

### CROSS-REFERENCE TO RELATED PATENT APPLICATIONS

This application claims priority to Korean Patent Application No. 10-2005-0067409, filed on Jul. 25, 2005, the contents of which are herein incorporated by reference in its entirety.

### BACKGROUND OF THE INVENTION

1. Technical Field

The present disclosure relates to a semiconductor integrated circuit and, more particularly, to a semiconductor integrated circuit capable of reducing power consumption due to a long transmission line between a transmitting circuit and a receiving circuit that are included in the semiconductor integrated circuit.

2. Discussion of the Related Art

FIG. 1 is a circuit diagram illustrating a conventional semiconductor integrated circuit. Referring to FIG. 1, a semiconductor integrated circuit includes a transmitting circuit 1, a receiving circuit 2 and a transmission line 3 electrically connecting the transmitting circuit 1 with the receiving circuit 2.

In general, in semiconductor integrated circuits with long routing lines, power consumption is increased and the transmission speed is decreased due to the parasitic resistance and parasitic capacitance caused by the long routing lines.

A need exists for a semiconductor integrated circuit capable of reducing power consumption and increasing the transmission speed in a semiconductor integrated circuit that includes a long transmission line.

### SUMMARY OF THE INVENTION

In an exemplary embodiment of the present invention, a transmitting circuit includes an internal circuit, a first dividing circuit, a second dividing circuit, a delay circuit, a first switching circuit, and a second switching circuit. The first dividing circuit is coupled between a first power voltage and the internal circuit, and the second dividing circuit is coupled between a second power voltage and the internal circuit. The delay circuit generates a switching control signal by delaying an output signal of the internal circuit for a delay time. The first switching circuit is coupled in parallel to the first dividing circuit, and the first switching circuit is coupled between the first power voltage and the internal circuit. The first switching circuit is switched in response to the switching control signal. The second switching circuit is coupled in parallel to the second dividing circuit, and the second switching circuit is coupled between the second power voltage and the internal circuit. The second switching circuit is switched in response to the switching control signal.

The internal circuit may include an inverter configured to invert an input signal to generate an output signal of the internal circuit.

The first switching circuit and the second switching circuit may be activated during the delay time that is determined by the delay circuit.

The first dividing circuit may include a diode-connected first PMOS transistor, and the second dividing circuit may include a diode-connected first NMOS transistor.

The first switching circuit may include a second PMOS transistor, and the second switching circuit may include a second NMOS transistor.

An absolute value of a threshold voltage of the first PMOS transistor may be less than an absolute value of a threshold voltage of the second PMOS transistor.

An absolute value of a threshold voltage of the first NMOS transistor may be less than an absolute value of a threshold voltage of the second NMOS transistor.

In an exemplary embodiment of the present invention, a semiconductor integrated circuit includes a transmitting circuit configured to control a range of an output signal swing based on a switching control signal that is delayed with respect to the output signal, a receiving circuit, and a transmission line connecting the transmitting circuit with the receiving circuit.

The transmitting circuit includes an internal circuit, a first dividing circuit, a second dividing circuit, a delay circuit, a first switching circuit, and a second switching circuit.

The first dividing circuit is coupled between a first power voltage and the internal circuit, and the second dividing circuit is coupled between a second power voltage and the internal circuit. The delay circuit generates a switching control signal by delaying an output signal of the internal circuit for a delay time and configured to generate a switching control signal. The first switching circuit is coupled in parallel to the first dividing circuit, and the first switching circuit is coupled between the first power voltage and the internal circuit. The first switching circuit is switched in response to the switching control signal. The second switching circuit is coupled in parallel to the second dividing circuit, and the second switching circuit is coupled between the second power voltage and the internal circuit. The second switching circuit is switched in response to the switching control signal.

The present invention will become readily apparent to those of ordinary skill in the art when descriptions of exemplary embodiments thereof are read with reference to the accompanying drawings.

### BRIEF DESCRIPTION OF THE DRAWINGS

FIG. 1 is a circuit diagram illustrating a conventional semiconductor integrated circuit.

FIG. 2 is a circuit diagram illustrating a semiconductor integrated circuit according to an exemplary embodiment of the present invention.

FIG. 3 is a timing diagram associated with the semiconductor integrated circuit shown in FIG. 2.

### DESCRIPTION OF EXEMPLARY EMBODIMENTS

Exemplary embodiments of the present invention will be described in detail with reference to the accompanying drawings. However, specific structural and functional details disclosed herein are merely representative for purposes of describing exemplary embodiments of the present invention. The present invention may be embodied in numerous alternate forms and should not be construed as limited to the exemplary embodiments set forth herein.

It should be understood that the intention is to cover all modifications, equivalents, and alternatives falling within the spirit and scope of the invention. Like reference numerals refer to similar or identical elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

FIG. 2 is a circuit diagram illustrating a semiconductor integrated circuit 205 according to an exemplary embodiment of the present invention.

Referring to FIG. 2, the semiconductor integrated circuit 205 includes a transmitting circuit 10, a receiving circuit 20, and a transmission line 30 electrically connecting the transmitting circuit with the receiving circuit.

The transmitting circuit 10 includes an internal circuit 11, a first dividing circuit 12, a second dividing circuit 13, a delay circuit 14, a first switching circuit 15, and a second switching circuit 16.

The first dividing circuit 12 is coupled in series between a power voltage VINT and the internal circuit 11. The second dividing circuit 13 is coupled in series between a ground voltage and the internal circuit 11.

The delay circuit 14 may be implemented with an inverter chain. The delay circuit 14 delays an output signal of the internal circuit 11 for a delay time to generate a switching control signal VC. The first switching circuit 15, which is coupled in series between the power voltage VINT and the internal circuit 11, is configured to switch in response to the switching control signal VC. The second switching circuit 16, which is coupled in series between the ground voltage and the internal circuit 11, is configured to switch in response to the switching control signal VC.

The internal circuit 11 may be an inverter. In an exemplary embodiment of the present invention, internal circuit 11 includes a PMOS transistor MP3 and an NMOS transistor MN3, and an output signal VA of the internal circuit 11 corresponds to the inverted input signal IN of the internal circuit 11.

The first dividing circuit 12 may include a diode-connected PMOS transistor MP4, and the second dividing circuit 13 may include a diode-connected NMOS transistor MN4. The first switching circuit 15 includes a PMOS transistor MP5, and the second switching circuit 16 may include a NMOS transistor MN5.

The receiving circuit 20 may be an inverter. The receiving circuit 20 may include a PMOS transistor MP6 and a NMOS transistor MN6.

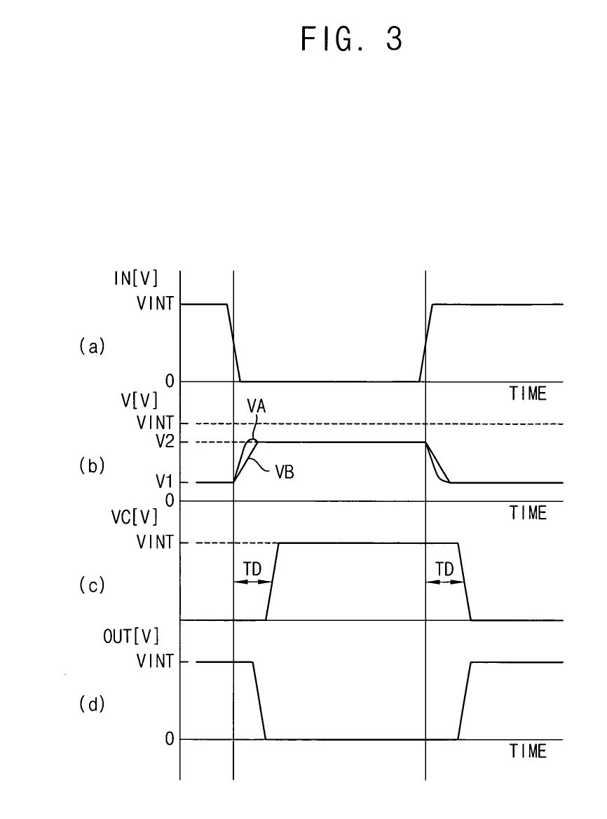

FIG. 3 is a timing diagram associated with the semiconductor integrated circuit shown in FIG. 2.

Referring to FIG. 3, the waveform (a) corresponds to the input voltage IN, waveform (b) corresponds to the output signal VA of the transmitting circuit 10 and an input signal VB of the receiving circuit 20, waveform (c) corresponds to the switching control signal VC (that is, an output signal of the delay circuit 14), and waveform (d) corresponds to an output signal OUT of the receiving circuit 20.

Hereinafter, operations of the semiconductor integrated circuit according to an exemplary embodiment of the present invention will be explained with reference to FIG. 2 and FIG. 3.

There are circuit blocks performing various functions in the semiconductor integrated circuit 205.

A long routing line between the transmitting circuit 10 and the receiving circuit 20 may be included in the semiconductor integrated circuit 205. For example, the transmission line 30 may be a long routing line.

The semiconductor integrated circuit 205, according to an exemplary 15 embodiment of the present invention illustrated in FIG. 2, is configured to reduce a range of the output voltage swing of the transmitting circuit 10, and power consumption may be reduced and the transmission speed may be increased.

The transmitting circuit 10 outputs a first output signal VA by inverting the input signal IN and buffering the inverted input signal. The first output signal VA passes through a routing line, such as the transmission line 30, and is inputted to the receiving circuit 20. The receiving circuit 20 generates a second output signal OUT by inverting the input signal VB received through the transmission line 30 and buffering the inverted input signal.

The first dividing circuit 12 may be implemented with the diode-connected PMOS transistor MP4. The first dividing circuit 12 provides the internal circuit 11 with a voltage that is lower than the power voltage VINT by as much as the threshold voltage Vthp of the PMOS transistor (MP4). The PMOS transistor MP4 may have a low threshold voltage (low Vth).

The second dividing circuit 13 may be implemented with the diode-connected NMOS transistor MN4. The second dividing circuit 13 provides the internal circuit 11 with a voltage that is lower than the power voltage VINT by as much as the threshold voltage Vthn of the NMOS transistor MN4. The NMOS transistor MN4 may have a low threshold voltage (low Vth).

When the input signal IN transitions from a logic high to a logic low state, the output signal VA of the transmitting circuit 10 transitions from a logic low to a logic high state. As shown in FIG. 3, the input signal VB of the receiving circuit 20 is a delayed signal with respect to the output signal VA of the transmitting circuit 10. The output signal OUT of the receiving circuit 20 is generated in response to the input signal VB of the receiving circuit 20, and is delayed with respect to the input signal IN such as illustrated in waveform (d) of FIG. 3. After the output signal VA of the transmitting circuit 10 transitions from a logic low to a logic high state, the switching control signal VC, that is, an output signal of the delay circuit 14, is delayed for a first delay time TD1 and transitions from a logic low to a logic high state.

In an exemplary embodiment of the present invention, the first delay time TD1 corresponds to the time interval between a high-to-low transition of the input signal IN and a low-to-high transition of the switching control signal VC. During the first delay time TD1, the PMOS transistor MP5 of the first switching circuit 15 is turned on, and provides current to an output terminal of the transmitting circuit 10 through the PMOS transistor MP3. The PMOS transistor MP5 is turned off after the first delay time TD1, since the output signal VA of the transmitting circuit 10 transitions from a logic low to a logic high state. According to an exemplary embodiment of the present invention, the PMOS transistor MP5 is turned on only while the output signal VA of the transmitting circuit 10 transitions from a logic low to a logic high state, and the rising time of the output signal VA of the transmitting circuit 10 may be decreased.

When the input signal IN transitions from a logic low to a logic high state, the output signal VA of the transmitting circuit 10 transitions from a logic high to a logic low state. As shown in FIG. 3, the input signal VB of the receiving circuit 20 is a delayed signal with respect to the output signal VA of the transmitting circuit 10. The output signal OUT of the receiving circuit 20 is generated in response to the input signal VB of the receiving circuit 20, and is delayed with respect to the input signal IN such as illustrated in waveform (d) of FIG. 3. After the output signal VA of the transmitting circuit 10 transitions from a logic high to a logic low state, the switching control signal VC, that is, an output signal of the delay circuit 14, is delayed for a second delay time TD2 and transitions from a logic high to a logic low state.

In an exemplary embodiment of the present invention, the second delay time TD2 corresponds to the time interval between a low-to-high transition of the input signal IN and a high-to-low transition of the switching control signal VC. During the second delay time TD2, the NMOS transistor MN5 of the second switching circuit 16 is turned on, and provides current to an output terminal of the transmitting circuit 10 through the NMOS transistor MN3. The NMOS transistor MN5 is turned off after the second delay time TD2, since the output signal VA of the transmitting circuit 10 transitions from a logic high to a logic low state. According to an exemplary embodiment of the present invention, the NMOS transistor MN5 is turned on only while the output signal VA of the transmitting circuit 10 transitions from a logic high to a logic low state, and the falling time of the output signal VA of the transmitting circuit 10 may be decreased.

The first switching circuit 15 and the second switching circuit 16 are turned on only during the first and second delay time TD1 and TD2, respectively, which are determined by the delay circuit 14.

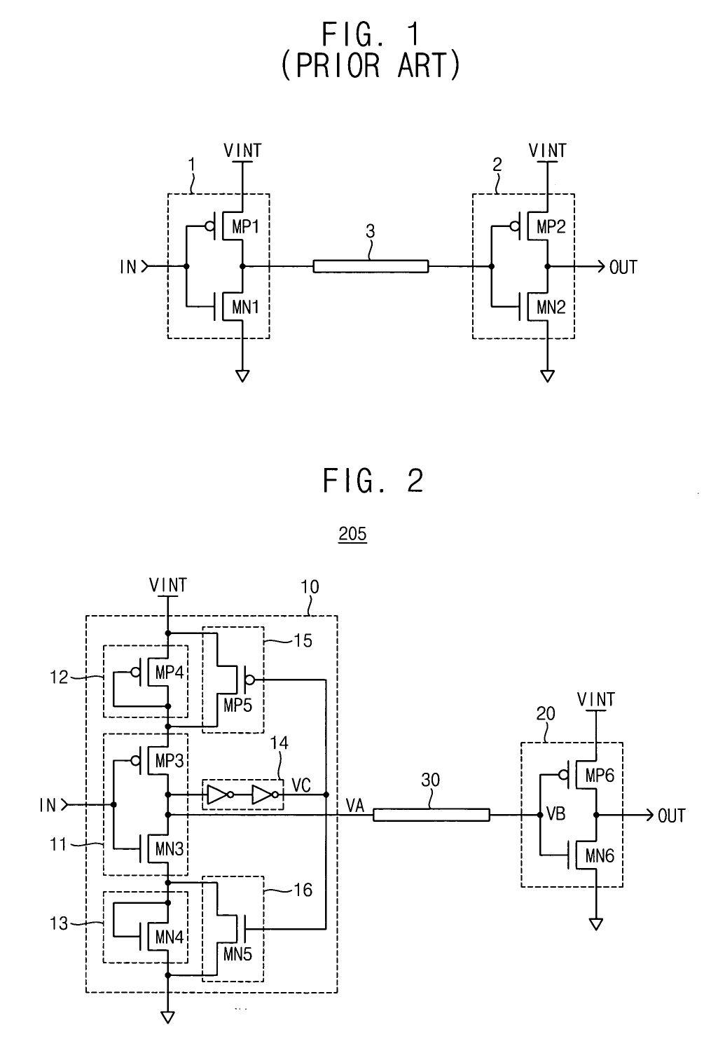

Referring to waveform (b) of FIG. 3, the output signal VA of the transmitting circuit 10 swings between a first voltage V1 and a second voltage V2. The first voltage V1 represents a voltage level having a value of (GND+Vthn), and the second voltage V2 represents a voltage level having a value of (VINT−Vthp). The output signal VA of the transmitting circuit 1 of the conventional semiconductor integrated circuit of FIG. 1 swings between the power voltage VINT and the ground voltage.

Power consumption P of the semiconductor integrated circuit according to an exemplary embodiment of the present invention may be represented as Equation 1.
P=Ctot×Vswing²/T (1)

In Equation 1, Ctot represents a total capacitance of the semiconductor integrated circuit including a parasitic capacitance caused by the transmission line 30. That is, the routing line, Vswing represents the swing range of the output signal, and T represents a period of the output signal.

Referring to Equation 1, the power consumption P of the semiconductor integrated circuit is proportional to the square of the swing range Vswing of the output signal. The output signal VA of the transmitting circuit 10 swings between the value of (VINT−Vthp) and the value of (GND+Vthn). The output signal VA of the transmitting circuit 10 has the value of (VINT−Vthp) when the input signal IN is a logic low state and the PMOS transistor MP3 is turned on. The output signal VA of the transmitting circuit 10 has the value of (GND+Vthn) when the input signal is a logic high state and the NMOS transistor MN4 is turned on.

The swing range of the output signal VA of the transmitting circuit 10 is determined by the PMOS transistor MP4 of the first dividing circuit 12, and by the NMOS transistor MN4 of the second dividing circuit 13. In accordance with an exemplary embodiment of the present invention, an absolute value of a threshold voltage of the PMOS transistor MP4 is less than an absolute value of a threshold voltage of the PMOS transistor MP5 of the first switching circuit 15, and an absolute value of a threshold voltage of the NMOS transistor MN4 is less than an absolute value of a threshold voltage of the NMOS transistor MN5 of the second switching circuit.

As described above, a transmitting circuit and a semiconductor integrated circuit according to an exemplary embodiment of the present invention include dividing circuits and switching circuits. According to an exemplary embodiment of the present invention, power consumption may be reduced and the transmission speed may be increased by decreasing a swing range of an output voltage, in cases when a long transmission line exists between any circuit blocks of the semiconductor integrated circuit.

Although the exemplary embodiments of the present invention have been described with reference to the accompanying drawings for the purpose of illustration, it is to be understood that the inventive processes and circuits are not to be construed as limited thereby. It will be readily apparent to those of ordinary skill in the art that various modifications to the foregoing exemplary embodiments may be made without departing from the scope of the invention as defined by the appended claims, with equivalents of the claims to be included therein.

What is claimed is:

1. A transmitting circuit, comprising:
an internal circuit;
a first dividing circuit coupled between a first power voltage and the internal circuit;
a second dividing circuit coupled between a second power voltage and the internal circuit;
a delay circuit configured to generate a switching control signal by delaying an output signal of the internal circuit for a delay time;
a first switching circuit coupled in parallel to the first dividing circuit, wherein the first switching circuit is coupled between the first power voltage and the internal circuit and configured to be switched in response to the switching control signal; and
a second switching circuit coupled in parallel to the second dividing circuit, wherein the second switching circuit is coupled between the second power voltage and the internal circuit and configured to be switched in response to the switching control signal.

2. The transmitting circuit of claim 1, wherein the internal circuit comprises an inverter configured to invert an input signal to generate an output signal of the internal circuit.

3. The transmitting circuit of claim 1, wherein the first switching circuit and the second switching circuit are activated during the delay time that is determined by the delay circuit.

4. The transmitting circuit of claim 1, wherein the first dividing circuit includes a diode-connected first PMOS transistor, and the second dividing circuit includes a diode-connected first NMOS transistor.

5. The transmitting circuit of claim 4, wherein the first switching circuit includes a second PMOS transistor, and the second switching circuit includes a second NMOS transistor.

6. The transmitting circuit of claim 4, wherein an absolute value of a threshold voltage of the first PMOS transistor is less than an absolute value of a threshold voltage of the second PMOS transistor.

7. The transmitting circuit of claim 4, wherein an absolute value of a threshold voltage of the first NMOS transistor is less than an absolute value of a threshold voltage of the second NMOS transistor.

8. A semiconductor integrated circuit comprising:
a transmitting circuit configured to control a range of an output signal swing based on a switching control signal that is delayed with respect to the output signal;
a receiving circuit; and
a transmission line connecting the transmitting circuit with the receiving circuit.

9. The semiconductor integrated circuit of claim 8, wherein the transmitting circuit comprises:
an internal circuit;
a first dividing circuit coupled between a first power voltage and the internal circuit;
a second dividing circuit coupled between a second power voltage and the internal circuit;
a delay circuit configured to generate the switching control signal by delaying an output signal of the internal circuit for a delay time;
a first switching circuit coupled in parallel to the first dividing circuit, wherein the first switching circuit is coupled between the first power voltage and the internal circuit and configured to be switched in response to the switching control signal; and
a second switching circuit coupled in parallel to the second dividing circuit, wherein the second switching circuit is coupled between the second power voltage and the internal circuit and configured to be switched in response to the switching control signal.

10. The semiconductor integrated circuit of claim 8, wherein the internal circuit comprises an inverter configured to invert an input signal to generate an output signal of the internal circuit.

11. The semiconductor integrated circuit of claim 8, wherein the first switching circuit and the second switching circuit are activated during the delay time that is determined by the delay circuit.

12. The semiconductor integrated circuit of claim 8, wherein the first dividing circuit comprises a diode-connected first PMOS transistor, and the second dividing circuit comprises a diode-connected first NMOS transistor.

13. The semiconductor integrated circuit of claim 12, wherein the first switching circuit comprises a second PMOS transistor, and the second switching circuit comprises a second NMOS transistor.

14. The semiconductor integrated circuit of claim 12, wherein an absolute value of a threshold voltage of the first PMOS transistor is less than an absolute value of a threshold voltage of the second PMOS transistor.

15. The semiconductor integrated circuit of claim 12, wherein an absolute value of a threshold voltage of the first NMOS transistor is less than an absolute value of a threshold voltage of the second NMOS transistor.
